(19) United States
(12) Patent Application Publication
(10) Pub. No.: US 2021/0165924 A1
(43) Pub. Date: Jun. 3, 2021

(54) A PORTABLE TERMINAL FOR GENERATING FLOOR PLANS BASED ON POINTING WALLS

(71) Applicant: ARCHIDRAW. INC., Seoul (KR)

(72) Inventors: Hee Seop YOON, Seoul (KR); Jeppe Bo ANDERSEN, Seoul (KR)

(21) Appl. No.: 16/611,940

(22) PCT Filed: Aug. 28, 2019
(86) PCT No.: PCT/KR2019/010992

§ 371 Date: Nov. 8, 2019

(30) Foreign Application Priority Data
Jul. 3, 2019 (KR) 10-2019-0079904
Aug. 16, 2019 (KR) 10-2019-0100088

(51) Int. Cl. G06F 30/13; G06F 30/12

(52) U.S. Cl. CPC G06F 30/13; G06F 30/12

(57) ABSTRACT

A portable terminal operation method includes the steps of: acquiring measurement information corresponding to a first coordinate point of a first wall and a second coordinate point of the first wall; determining structure information of the first wall connecting the first coordinate point and the second coordinate point on the basis of a linear function operation of the first coordinate point and the second coordinate point; and completing indoor structure information including one or more closed spaces, according to sequential connection processing of other walls in a first direction corresponding to the first wall.

### TECHNICAL FIELD

The present invention relates to a portable terminal and an operating method thereof, and more specifically, to a portable terminal for generating indoor structure information based on wall pointing, and an operating method thereof.

### BACKGROUND ART

Generally, in designing drawings of a building, a CAD program is installed in a personal computer or a notebook computer, and drawings are created and resulting materials are produced using a device such as a mouse or a tablet.

However, as the society progresses from an industrial society to an information society, virtual reality techniques capable of substituting for the functions of a display house or the like by providing users with three-dimensional modeling results, not a drawing, more easily in the form of a user experience are on the rise.

For example, various methods are proposed to create virtual reality (VR) or augmented reality (AR) for the purpose of virtual tour of the interior of a building (house, apartment, office, hospital, church, etc.) or simulation of interior or furniture arrangement (or indoor simulation), and to provide users with simulated environments and situations based thereon to interact with each other.

To this end, a method of creating three-dimensional data of a building or an indoor structure in advance manually or using a 3D scanner and providing virtual reality based thereon may be used. However, since this method needs a process of modeling a three-dimensional building by estimation from scanned information or drawings, there is a problem of degrading accuracy due to the limit of data processing and handworks, as well as the difficulties of manufacturing.

To solve this problem, technique of recognizing an indoor structure, furniture or the like from an image using a camera function of a portable terminal are proposed. However, techniques like this are also based on image analysis and estimation and may not calculate an accurate indoor structure, and have difficulties in calculating specific information of a completed indoor structure such as a floor plan of a building since images of only a specific direction are utilized.

Accordingly, time and cost are excessively required in reality to structure and create indoor information of a building with only the current techniques.

### DISCLOSURE OF INVENTION

### Technical Problem

Therefore, the present invention has been made in view of the above problems, and it is an object of the present invention to provide a portable terminal for creating indoor structure information based on wall pointing and an operating method thereof, which can create indoor structure information based on sequential wall pointing on the basis of distance measurement and three-dimensional angle measurement associated with the portable terminal so that a user may intuitively and conveniently create the indoor structure information and, particularly, create a floor plan of a building close to actual measurement with only a few inputs into the portable terminal.

### Technical Solution

To accomplish the above object, according to one aspect of the present invention, there is provided a portable terminal operation method comprising the steps of: acquiring measurement information corresponding to a first coordinate point of a first wall and a second coordinate point of the first wall; determining structure information of the first wall connecting the first coordinate point and the second coordinate point on the basis of a linear function operation of the first coordinate point and the second coordinate point; and completing indoor structure information including one or more closed spaces, according to sequential connection processing of other walls in a first direction corresponding to the first wall.

In addition, according to another aspect of the present invention, there is provided a portable terminal operation method comprising the steps of: acquiring measurement information corresponding to a first coordinate point of a first wall and a second coordinate point of the first wall; determining structure information of the first wall connecting the first coordinate point and the second coordinate point on the basis of a linear function operation of the first coordinate point and the second coordinate point; completing indoor structure information including one or more closed spaces, according to sequential connection processing of other walls in a first direction corresponding to the first wall; and performing a calibration process of the indoor structure information according to user input.

In addition, according to another aspect of the present invention, there is provided a portable terminal comprising: a measurement unit for acquiring measurement information corresponding to a first coordinate point of a first wall and a second coordinate point of the first wall; a space information creation unit for determining structure information of the first wall connecting the first coordinate point and the second coordinate point on the basis of a linear function operation of the first coordinate point and the second coordinate point, and completing indoor structure information including one or more closed spaces, according to sequential connection processing of other walls in a first direction corresponding to the first wall; and a calibration unit for performing a calibration process of the indoor structure information according to user input.

In addition, according to another aspect of the present invention, there is provided a portable terminal operation method comprising the steps of: acquiring user input and measurement information corresponding to the first coordinate point of the first wall; calculating location information of a two-dimensionally converted first coordinate point on the basis of user's location information, three-dimensional angle information and distance information acquired from the measurement information; acquiring user input and measurement information corresponding to the second coordinate point of the first wall; calculating location information of a two-dimensionally converted second coordinate point on the basis of three-dimensional angle information and distance information acquired from the measurement information; determining structure information of the first wall connecting the first coordinate point and the second coordinate point on the basis of a linear function operation; and creating the indoor structure information including the structure information of the first wall.

In addition, according to another aspect of the present invention, there is provided a portable terminal comprising: a measurement unit for acquiring user input and measurement information corresponding to the first coordinate point of the first wall, and acquiring user input and measurement information corresponding to the second coordinate point of the first wall; a coordinate processing unit for calculating location information of a two-dimensionally converted first coordinate point on the basis of user's location information, three-dimensional angle information and distance information acquired from the measurement information, and calculating location information of a two-dimensionally converted second coordinate point on the basis of three-dimensional angle information and distance information acquired from the measurement information; and a space information creation unit for determining structure information of the first wall connecting the first coordinate point and the second coordinate point on the basis of a linear function operation, and creating the indoor structure information including the structure information of the first wall.

Meanwhile, a method according to an embodiment of the present invention for solving the problems may be implemented as a program for executing the method in a computer and a recording medium recording the program.

### Advantageous Effects

According to an embodiment of the present invention, as location information of each coordinate point corresponding to a first coordinate point and a second coordinate point of a first wall measured on the basis of distance measurement and three-dimensional angle measurement associated with a portable terminal is calculated, and information on the structure of the first wall is determined on the basis of a linear function operation connecting the coordinate points, interior floor plan information including structure information of the first wall can be created, and indoor structure information based on sequential wall pointing can be created thereafter according to connection of walls.

Accordingly, the present invention may provide a portable terminal for creating indoor structure information based on wall pointing and an operating method thereof, which allow a user to intuitively and conveniently create indoor structure information and particularly create a floor plan of a building close to actual measurement with only a few inputs into the portable terminal.

In addition, the present invention can provide a more efficient process of calibrating indoor structure information while maintaining the polygonal shape of the overall indoor structure information and minimizing user input into an interface by calibrating accuracy of corner angles through measurement and prediction of errors and providing proper calibration and scaling calibration through efficiently process of user input for calibrating the accuracy varying according to the function and performance of the portable terminal.

### BRIEF DESCRIPTION OF THE DRAWINGS

FIG. 1 is a view showing a portable terminal according to an embodiment of the present invention.

FIG. 2 is a block diagram more specifically showing a portable terminal according to an embodiment of the present invention.

FIG. 3 is a block diagram more specifically showing a space information creation unit according to an embodiment of the present invention.

FIG. 4 is a flowchart illustrating a method of operating a portable terminal according to an embodiment of the present invention.

FIGS. 5 and 6 are views showing a process of creating indoor structure information in steps according to an embodiment of the present invention.

FIGS. 7 to 12 are views illustrating a user interface outputted from a portable terminal according to an embodiment of the present invention.

FIG. 13 a flowchart schematically illustrating a calibration process according to an embodiment of the present invention.

FIG. 14 is a flowchart illustrating an angle and node position calibration process based on polygon calibration according to an embodiment of the present invention, and FIGS. 15 to 23 are views showing an example of the calibration process in steps.

FIG. 24 is a flowchart illustrating a polygon scaling calibration process according to an embodiment of the present invention, and FIGS. 25 to 30 are views showing an example of a user interface for polygon scaling and a calibration result.

Hereinafter, only the principle of the present invention will be described. Therefore, those skilled in the art may implement the principle of the present invention that is not clearly described or shown in this specification and invent various apparatuses included within the concept and scope of the present invention. In addition, it should be understood that, in principle, all the conditional terms and embodiments arranged in this specification should be clearly intended only for the purpose understanding the concept of the present invention and are not restrictive to the embodiments and states specially arranged like this.

In addition, it should be understood that all the detailed descriptions arranging specific embodiments, as well as the principle, viewpoint and embodiments of the present invention, are intended to include structural and functional equivalents thereof. In addition, it should be understood that these equivalents include the equivalents that will be developed in the future, as well as the equivalents open to the public presently, i.e., all components invented to perform the same function regardless of the structure.

Accordingly, for example, block diagrams of the present invention should be understood as showing a conceptual viewpoint of an exemplary circuit which specifies the principle of the present invention. Similarly, all flowcharts, state transition diagrams, pseudo codes and the like should be understood as being practically stored in a computer-readable medium and showing various processes performed by a computer or a processor regardless of whether the computer or the processor is clearly shown in the figure.

The functions of various components shown in the figures including a processor or a function block that is displayed as a concept similar thereto may be provided using hardware capable of executing software in relation to proper software, as well as dedicated hardware. When being provided by the processor, the functions may be provided by a single dedicated processor, a single shared processor or a plurality of individual processors, and some of these may be shared.

In addition, clear use of a term presented as a processor, a controller or a concept similar thereto should not be interpreted by exclusively quoting hardware capable of executing software and should be understood to implicitly include digital signal processor (DSP) hardware and ROM, RAM and non-volatile memory for storing the software without limit. It may include already-known other hardware.

In the claims of this specification, the constitutional components expressed as a means for performing a function disclosed in the detailed description are intended to include, for example, all methods performing the functions including all forms of software including a combination of circuit elements or firmware/microcode or the like performing the functions, and combined with appropriate circuits for executing the software to perform the functions. Since the present invention defined by the claims combines the functions provided by diversely arranged means and is combined with the methods requested by the claims, it should be understood that any means which can provide the functions is equivalent to those grasped from this specification.

The objects, features and advantages described above will be further clear through the following detailed descriptions related to the accompanying drawings, and therefore, those skilled in the art may easily embody the spirit of the present invention. In addition, in describing the present invention, when it is determined that the detailed description of known techniques related to the present invention may unnecessarily blur the gist of the present invention, the detailed description will be omitted.

Hereinafter, preferred embodiments according to the present invention will be described in detail with reference to the accompanying drawings.

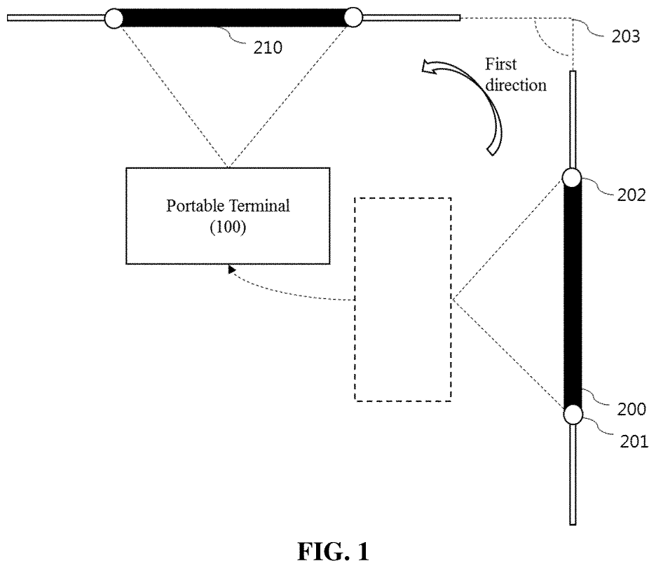

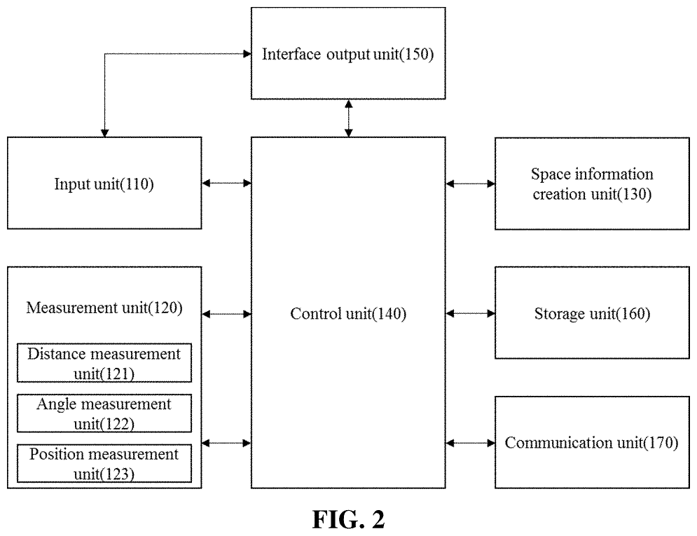

FIG. 1 is a view showing a portable terminal according to an embodiment of the present invention, and FIG. 2 is a block diagram more specifically showing a portable terminal according to an embodiment of the present invention.

The portable terminal 100 described in this specification may include various electronic devices, for example, a cellular phone, a smart phone, a computer, a laptop computer, a digital broadcasting terminal, a personal digital assistant (PDA), a portable multimedia player, a navigator, a virtual reality device and the like, which operate according to user input.

In addition, programs or applications for executing the methods according to the embodiments of the present invention may be installed and operate in the portable terminal 100.

Accordingly, the portable terminal 100 according to an embodiment of the present invention may provide an indoor structure information creation interface, and indoor structure information created according to an embodiment of the present invention may be stored in the portable terminal 100 or uploaded to a separate server (not shown) or the like and managed according to user information.

Here, the indoor structure information may include two-dimensional building floor plan information and structure information that can be used for simulation of interior in association with three-dimensional modeling information. In addition, the indoor structure information may include one or more walls and connection information of the walls and may form one or more closed spaces.

To facilitate creation of the indoor structure information, the portable terminal 100 may be provided with a distance measurement sensor and an angle measurement sensor, calculate a first coordinate point 201 and a second coordinate point 202 from measurement information corresponding to a first wall 200 pointed within a room according to user input, and determine structure information of the first wall 200 based on the first coordinate point 201 and the second coordinate point 202. The structure information of the first wall 200 may be calculated using an infinite linear function connecting the first coordinate point 201 and the second coordinate point 202, and the linear function may be determined for each of the walls 200 and 210.

Accordingly, the portable terminal 100 may extend the linear functions corresponding to the walls 200 and 210, identify an intersection 203 between the linear functions, process connection of the first wall and the second wall corresponding to the intersection 203, and predict a corner location and a corner angle between the intersections.

Particularly, although the corner location and the corner angle are very important factors for producing an interior floor plan of a building, it is difficult to accurately measure in an existing full scanning method or the like, and thus as the corner location and the corner angle according to an embodiment of the present invention are calculated as an intersection 203 between the linearly calculated extension lines of the first wall 200 and the second wall 210, the indoor structure information can be calculated very accurately.

In addition, according to an embodiment of the present invention, as the user repeatedly performs the measurement and connection process for each wall in the first direction until a closed space is formed, the indoor structure information can be completed.

To this end, the portable terminal 100 according to an embodiment of the present invention may provide a user interface which allows the user to intuitively perform pointing of two coordinate points of each wall and sequential input of wall creation in the first direction.

For example, although some of the conventional techniques includes a technique of measuring corners of a space and using the corners for calculating indoor structure information, there is a problem in that accurate measurement is almost impossible with only these measurements.

Contrarily, the portable terminal 100 according to an embodiment of the present invention may calculate an accurate wall structure by simply pointing only two coordinate points on the wall, and since the wall may be mapped to a linear function passing through the two measured points, walls and potential wall extension lines are calculated by repeating this process for all the walls of the indoor space, and information on the corner locations and angles according to connection of the lines can be accurately calculated.

However, to this end, the portable terminal 100 user needs to continuously measure the walls in a specific first direction (e.g., clockwise or counterclockwise), and accordingly, after a first wall is measured, a next second wall should be adjacent to the first wall, and the initial first direction should be maintained throughout the information creation process.

In addition, it is preferable that the portable terminal 100 moves at a predetermined speed or lower during the measurement. This is to enhance the accuracy in measuring the positions and the angles of the portable terminal 100.

In addition, the first coordinate point and the second coordinate point are preferably spaced apart from each other by a predetermined distance, and the height is preferably within a predetermined height. This is since that it is easy to calculate an exact linear function.

In addition, since the completed indoor structure information may be used for information sharing and storage and indoor simulation, the indoor simulation may include a function of visualizing a three-dimensional space similar to the reality in a virtual space displayed on the display of the portable terminal 100, and freely arranging three-dimensional objects corresponding thereto on the indoor simulation graphics based on the indoor structure information. Accordingly, the indoor simulation may be preferably used for floor plans simulating furniture or the like that will be arranged in the room, and a floor plan application may be included in an application which provides indoor simulation.

To this end, a separate server device may store the predetermined application that can be installed in the portable terminal 100 and information needed for providing the indoor simulation, and provide user registration for the user and indoor structure information management. The portable terminal 100 may download and install an application from the server device.

Detailed configurations of each device for implementing this function will be described below in detail.

FIG. 2 is a block diagram more specifically showing a portable terminal according to an embodiment of the present invention.

Referring to FIG. 2, the portable terminal 100 includes an input unit 110, a distance measurement unit 121, an angle measurement unit 122, a space information creation unit 130, a control unit 140, an interface output unit 150, a storage unit 160, and a communication unit 170. The constitutional components shown in FIG. 2 are not essential, and a terminal having constitutional components more or less than those can be implemented.

The communication unit 170 may include one or more modules which make wireless communication possible between the portable terminal 100 and a wireless communication system or between the portable terminal 100 and a network in which the portable terminal 100 is located. For example, the communication unit 170 may include a broadcast receiving module, a mobile communication module, a wireless Internet module, a short distance communication module, a location information module and the like.

The mobile communication module transmits and receives wireless signals with at least one among a server device, a base station, an external device, and a server on a mobile communication network.

The wireless Internet module refers to a module for wireless Internet access and may be embedded in or installed outside the portable terminal 100.

As the wireless Internet module, wireless LAN (WLAN) (Wi-Fi), wireless broadband (Wibro), world interoperability for microwave access (Wimax), high speed downlink packet access (HSDPA) or the like may be used.

The short distance communication module refers to a module for short distance communication. As a short distance communication technique, Bluetooth, radio frequency identification (RFID), infrared data association (IrDA), ultrawideband (UWB), ZigBee or the like may be used.

The location information module is a module for acquiring a position of the terminal, and a representative example thereof is a global positioning system (GPS) module.

In addition, for example, the communication unit 170 may upload completed indoor structure information to the server device or receive previously registered indoor structure information from the server device in response to user information.

The input unit 110 generates an input data needed for a user to control operation of the terminal. The user input unit 110 may be configured of a keypad, a dome switch, a touch pad (capacitive/resistive), a jog wheel, a jog switch or the like.

The measurement unit 120 measures and outputs information sensed through one or more sensors provided in the portable terminal 100. The measurement unit 120 may include a distance measurement unit 121, an angle measurement unit 122, and a position measurement unit 123.

The distance measurement unit 121 may include one or more distance measurement sensors for outputting information on the distance to a position pointed by the portable terminal 100. The distance measurement unit 121 may include various sensors, for example, an ultrasonic sensor, a laser sensor, an infrared sensor, a radar sensor, a camera sensor and the like, and preferably, it may be provided in a form detachable from the portable terminal 100.

In addition, the angle measurement unit 122 may include one or more state measurement sensors for outputting three-dimensional angle information corresponding to the current state of the portable terminal 100. For example, the angle measurement unit 122 may include a three-axis acceleration sensor for measuring whether the portable terminal 100 is inclined at a certain angle, or the like. Here, the measured angle information may be used for calculating a coordinate point of a wall, together with the distance information of the distance measurement unit 121, and particularly, three-axis angle information using a yaw axis, a pitch axis and a roll axis as three axes may be measured or calculated and outputted.

In addition, the position measurement unit 123 may include one or more sensors for outputting location information corresponding to the current position of the portable terminal 100 and may include various output sensors for calculating the location information, such as an acceleration sensor, a GPS sensor, an indoor position tracking sensor and the like. Particularly, the position measurement unit 123 may include one or more tracking sensors which allow position and head tracking of a user for simulation of augmented reality or virtual reality.

The interface output unit 150 is for generating an output related to visual, auditory or tactile sense through provision of an interface and may include a display unit, an acoustic output module, an alarm unit, a haptic module and the like.

The display unit displays (outputs) information processed in the portable terminal 100. For example, when the terminal is in an indoor simulation mode, it displays a user interface (UI) or a graphic user interface (GUI) related to indoor simulation and floor plan. In addition, a user interface for creating indoor structure information according to an embodiment of the present invention may be displayed on the interface screen.

The display unit may include at least one among a liquid crystal display (LCD), a thin film transistor-liquid crystal display (TFT LCD), an organic light-emitting diode (OLED), a flexible display, and a 3D display.

The storage unit 160 may store programs for operation of the control unit 140 and may temporarily store input and output data.

The storage unit 160 may include at least one type of storage medium among a flash memory type, a hard disk type, a multimedia card micro type, a card-type memory (e.g., SD or XD memory, etc.), Random Access Memory (RAM), Static Random Access Memory (SRAM), Read-Only Memory (ROM), Electrically Erasable Programmable Read-Only Memory (EEPROM), PROM (Programmable Read-Only Memory), magnetic memory, magnetic disk, and optical disk. The portable terminal 100 may operate in relation to a web storage which performs the storage function of the memory 160 on the Internet.

The space information creation unit 130 calculates wall structure information and wall connection information for creating indoor structure information on the basis of the distance information of the distance measurement unit 121 and the three-dimensional angle information of the angle measurement unit 122 according to input of the input unit 110 and control of the control unit 140, completes the indoor structure information according to formation of a closed space formed by sequentially connecting the walls, and performs an output process through the interface output unit 150.

To this end, the space information creation unit 130 may calculate a first coordinate point and a second coordinate point of each wall based on the distance information of the distance measurement unit 121 and the three-dimensional angle information of the angle measurement information 122, determine structure information of the first wall by connecting the first coordinate point and the second coordinate point, and perform calculation of corner locations and corner angles of the indoor structure information by performing a corner connection process with other walls according to a linear function operation of the structure information.

In addition, the space information creation unit 130 may create completed indoor structure information by performing a corner angle calibration process, and this may include an overall angle calibration process considering that the wall structure of a general interior floor plan has an angle of 90 degrees.

The control unit 140 controls general operation of a terminal and performs control and process related to, for example, creation of an indoor structure information, provision of an interface, voice communication, data communication, video communication and the like.

In addition, according to user input, the control unit 140 may store the indoor structure information including the wall structure information, corner location information, and corner angle information calculated according to creation of the space information in the storage unit 160, or transmit the indoor structure information to the server device through the communication unit 170.

Accordingly, the indoor structure information may be matched to user account information of the portable terminal 100, and stored and managed in a cloud server or a server device.

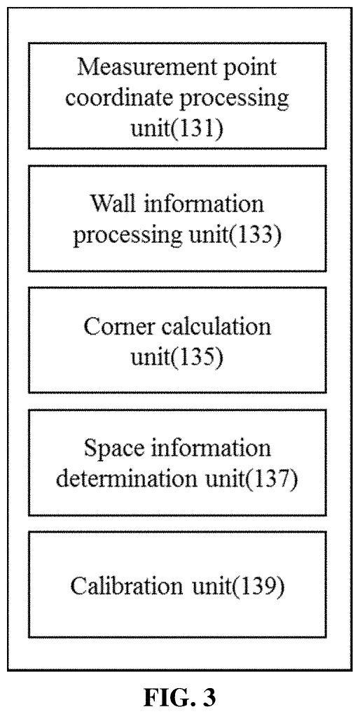

FIG. 3 is a block diagram more specifically showing a space information creation unit according to an embodiment of the present invention.

Referring to FIG. 3, the space information creation unit 130 includes a measurement point coordinate processing unit 131, a wall information processing unit 133, a corner calculation unit 135, a space information determination unit 137, and a calibration unit 139.

The measurement point coordinate processing unit 131 may calculate coordinates of a measurement point on a wall on the basis of the distance information and the three-dimensional angle information sensed by the distance measurement unit 121 and the angle measurement information 122, and output first coordinate information and second coordinate information corresponding to the first wall.

More specifically, the measurement point coordinate processing unit 131 may calculate coordinates of a measurement point on a wall on the assumption that the walls are formed to rise from the ground in the vertical direction in the form of a straight line, not a curved surface.

For example, the measurement point coordinate processing unit 131 may use the current position of a user measured by the position measurement unit 123 as a reference point, and measure pointing distance information from the current position to the wall of the pointed direction.

At this point, the measurement point coordinate processing unit 131 may calculate parallel distance information of a segment parallel to the ground through a cosine operation of the pointing distance information and pitch angle information among the current three-dimensional angle information, and this may be determined as two-dimensional distance information from the current position of the user to the wall. That is, this can be calculated as ‘parallel distance information from the user to the wall=pointed distance information x cos(pitch angle)’.

In addition, the measurement point coordinate processing unit 131 may calculate coordinate point information of a wall corresponding to the current position by calculating the parallel distance information and the yaw angle information among the three-dimensional angle information. If it is assumed that the parallel distance information is 1, the pitch angle is θ, the yaw angle information is ϕ, and the current position is (x0, y0), the current coordinate point information (x, y) may be calculated according to the operation as shown in mathematical expression 1.

(x, y)=(I*cos(θ)*(−sin(ϕ))+x₀, I*cos(θ)*(−cos(ϕ))+y₀) [Mathematical expression 1]

In addition, when the first coordinate point (x1, y1) of the first wall is measured, the measurement point coordinate processing unit 131 may additionally measure the second coordinate point (x2, y2) of the first wall. Here, the coordinate points corresponding to each wall may be at least two, and two coordinate points of the walls sequentially arranged in the first direction may be calculated according to provision of an interface.

In addition, when two or more coordinate points are calculated for each of the walls, the wall information processing unit 133 calculates wall structure information by processing a linear function operation corresponding to each of the coordinate points.

The wall information processing unit 133 may determine the wall structure information in the form of linear function equation (y=ax+b) connecting two coordinate points. The wall structure information may include a measured wall part and a predicted wall part formed to be infinitely extended from the wall part.

In addition, the corner calculation unit 135 may calculate corner information connecting the walls on the basis of intersection operation of each wall structure information, and the corner information may include corner location information and corner angle information.

More specifically, the corner calculation unit 135 may calculate slope s of the first wall and the second wall to calculate corner information between the first wall and the second wall, and calculate a y-intercept value with respect to a point on the wall as a reference. (y_0−s*x_0=b)

Here, if a first linear function of the first wall is ax+b=y and a second linear function of the second wall is cx+d=y, it may be calculated as x=(d−b)/(a−c) of the intersection point where x and y of the two linear functions are accorded to each other. Here, ‘a’ may be the slope of the first wall, ‘c’ may be the slope of the second wall, ‘b’ may be the y-intercept of the first wall, and ‘d’ may be the y-intercept of the second wall.

In addition, the corner calculation unit 135 may calculate y value by applying the x coordinate value calculated in advance to the linear function of the first wall or the second wall. Accordingly, (x, y) of the acquired corner location information may be calculated, and corner angle information may be calculated by the operation between the slopes of the first linear function and the second linear function in correspondence to the corner location information.

The space information determination unit 137 may determine space information connecting each corner and walls on the basis of the calculated wall structure information and corner information. For example, when a closed space is formed according to connection of each corner and the walls, the space information determination unit 137 may determine space information and assign a label such as room 1 or the like.

Meanwhile, the calibration unit 139 may perform a calibration process considering that the wall structure information is generally a right angle (90 degrees), in correspondence to the corner angle information of the corner information. For example, when the corner angle information is within a predetermined angle with respect to 90 degrees, the calibration unit 139 may perform a calibration process of calibrating the corner angle information to 90 degrees. Accordingly, the overall floor plan of the building can be accurately structured.

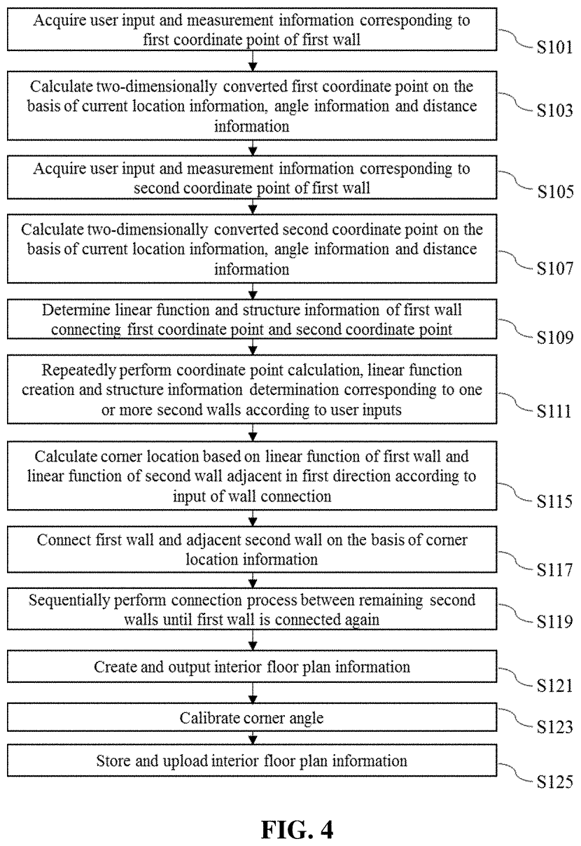

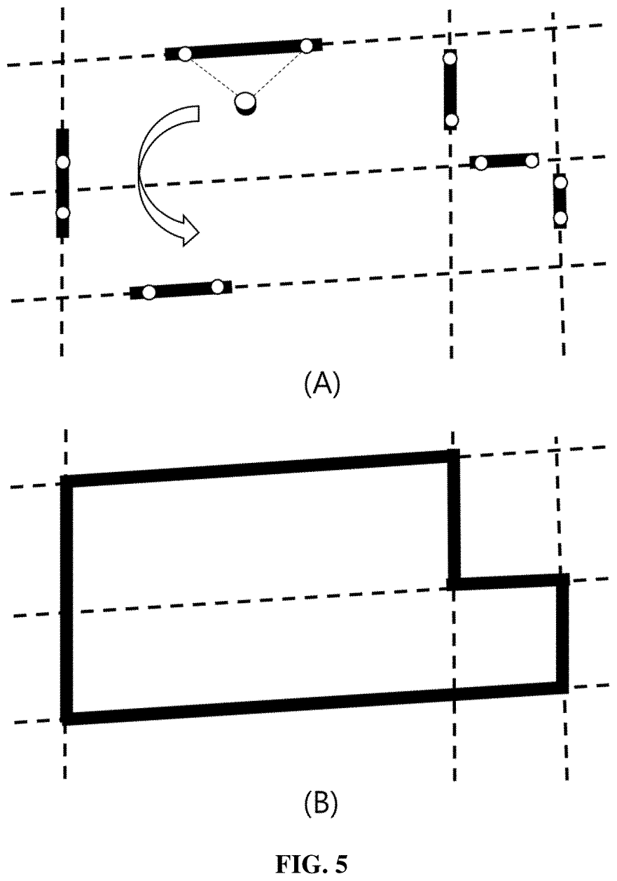

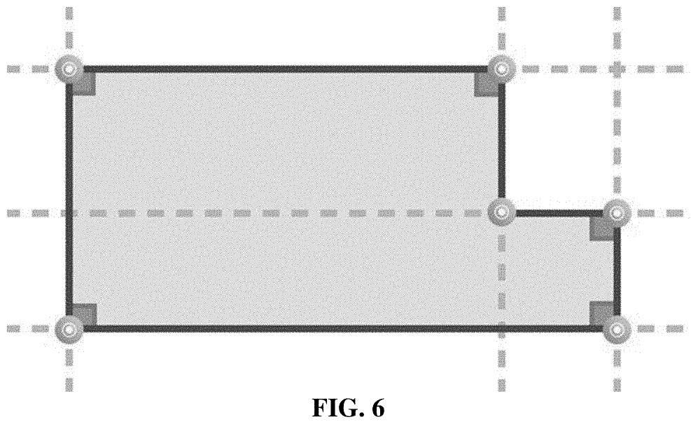

FIG. 4 is a flowchart illustrating a method of operating a portable terminal according to an embodiment of the present invention, and FIGS. 5 and 6 are views showing a process of creating indoor structure information in steps according to an embodiment of the present invention.

First, the portable terminal 100 acquires user input and measurement information corresponding to a first coordinate point of a first wall (step S101).

Then, the portable terminal 100 calculates a two-dimensionally converted first coordinate point on the basis of current location information, angle information and distance information (step S103).

Next, the portable terminal 100 acquires user input and measurement information corresponding to a second coordinate point of the first wall (step S105).

Then, the portable terminal 100 calculates a two-dimensionally converted second coordinate point on the basis of current location information, angle information and distance information (step 107).

Next, the portable terminal 100 determines a linear function and structure information of the first wall connecting the first coordinate point and the second coordinate point (step S109).

Then, the portable terminal 100 repeatedly performs coordinate point calculation, linear function creation and structure information determination corresponding to one or more second walls according to continuous user inputs (step S111).

Next, the portable terminal 100 calculates a corner location based on the linear function of the first wall and the linear function of the second wall adjacent in the first direction according to input of wall connection (step S115).

Then, the portable terminal 100 processes connection of the first wall and the adjacent second wall on the basis of corner location information through the space information determination unit 137 (step S117).

Then, the portable terminal 100 sequentially performs the connection process between the remaining second walls until the first wall is connected again (step S119).

Next, the portable terminal 100 may create and output information on the interior floor plan according to completion input of the user through the interface output unit 150 (step S121).

In addition, the portable terminal 100 may perform corner angle calibration through the calibration unit 139 (step S123) and perform a storage and upload process of interior floor plan information according to user input (step S125).

Here, the interior floor plan information may be planar structure information including two-dimensional wall information and corner information, and the two-dimensional structure information itself may be outputted, or the interior floor plan information may be converted into three-dimensional indoor simulation information and outputted as a three-dimensional graphic image of a form that the user may realistically feel.

FIGS. 5 and 6 are views showing a process of creating wall and indoor structure information according to the steps described above, and as shown in FIG. 5(A), the user may perform pointing to identify two coordinate points corresponding to each wall, and particularly, as the portable terminal 100 provides an interface which allows sequentially performing the pointing in the first direction, the wall connection may be accomplished normally.

In addition, when the sequential wall creation is completed, a closed space may be formed as shown in FIG. 5(B) by the linear function connection and corner information calculation of each wall, and the space information determination unit 137 may determine the indoor structure information according thereto.

In addition, as shown in FIG. 6, since the calibration unit 139 may predict an error value of each corner information and perform an angle calibration process of calibrating to 90 degrees when the error value is within a predetermined range compared with 90 degrees, more natural interior floor plan information may be calculated.

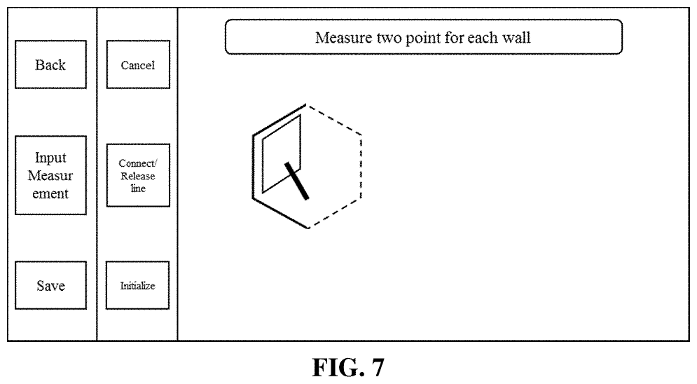

FIGS. 7 to 12 are views illustrating a user interface outputted from a portable terminal according to an embodiment of the present invention.

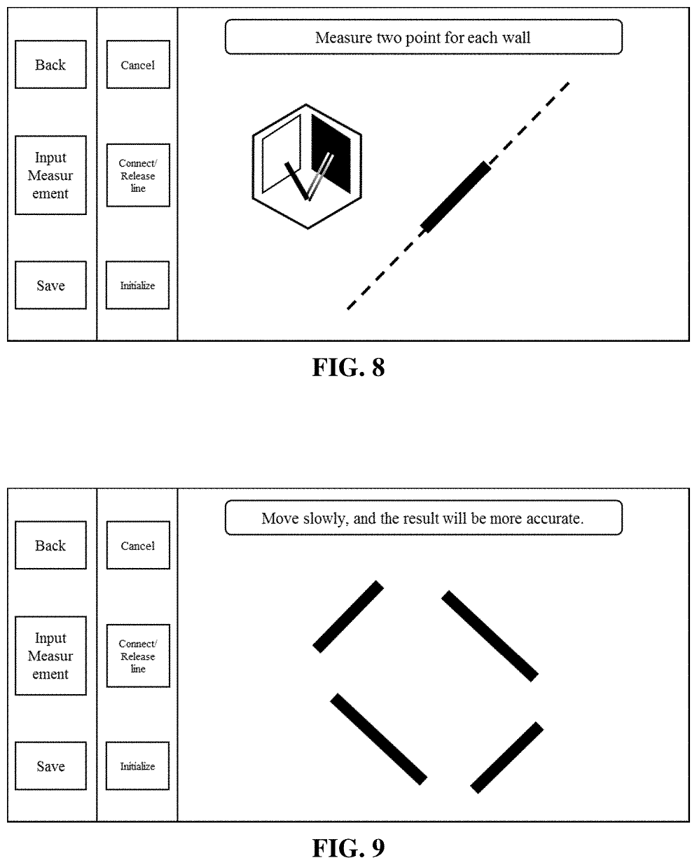

FIGS. 7 and 8 are views showing a wall measurement interface provided through the interface output unit 150, and an interface for measuring two points on each wall may be provided to the user, and a graphic image in which a wall is created whenever measurement of the two points is completed may be outputted through the interface output unit 150.

In addition, referring to FIG. 8, wall extension lines according to creation of a wall may be outputted together, and the wall extension lines may be predicted lines of the wall determined by a linear function and used for calculation of a corner.

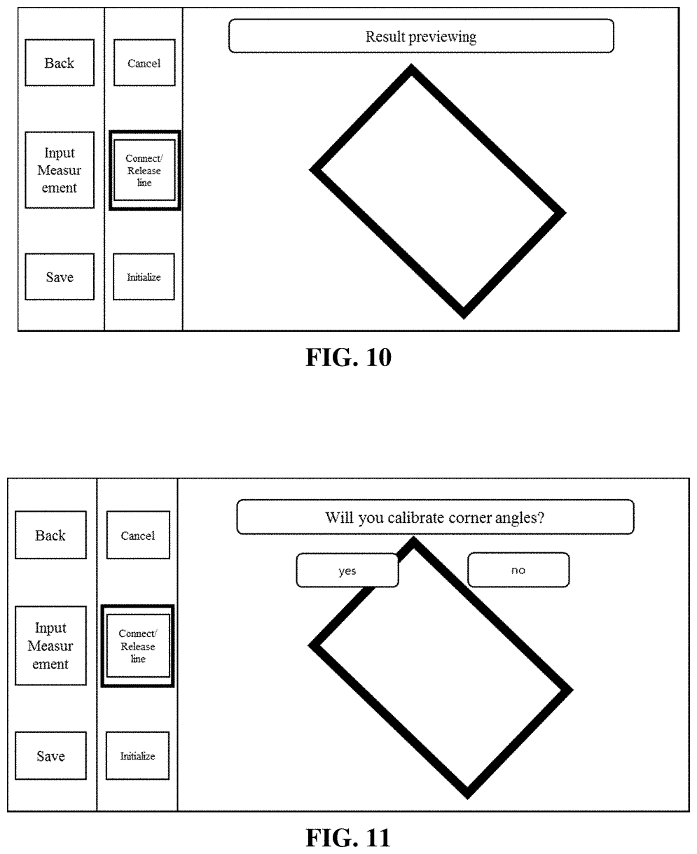

In addition, FIGS. 9 and 10 are views showing a wall connection interface in the case where the user inputs a line connection/release button when measurement of the walls is completed, and indoor structure information may be formed as the walls are connected by the process of the present invention described above. The user may preview the result and release the connection of walls by inputting the line connection/release button again when the measurement is wrong.

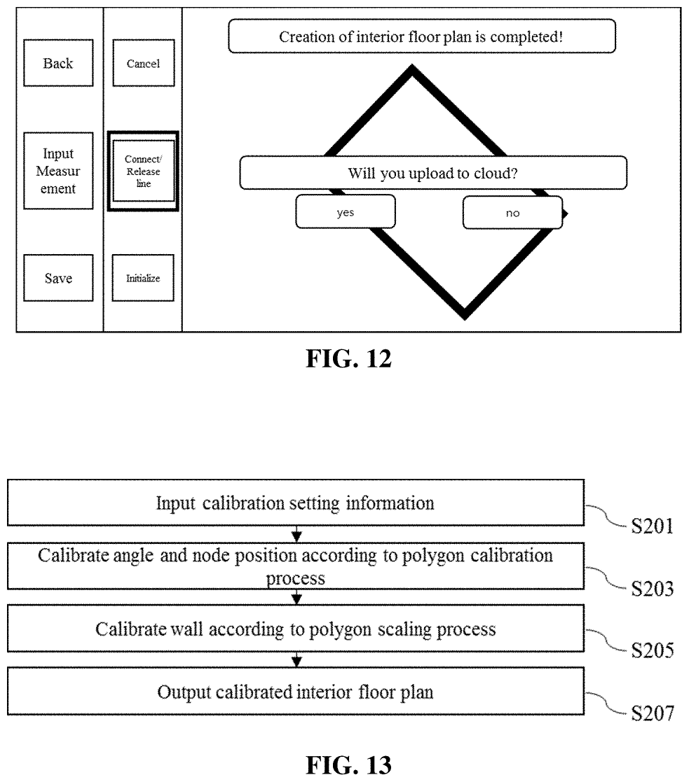

Meanwhile, FIGS. 11 and 12 are views showing an interface for final corner angle calibration and completion of creation, and the user may selectively input whether or not to calibrate a corner angle, and selectively input whether or not to upload information on the completed interior floor plan to the cloud or the server.

FIG. 13 a flowchart schematically illustrating a calibration process according to an embodiment of the present invention.

Referring to FIG. 13, the calibration unit 139 according to an embodiment of the present invention may perform an overall polygon calibration process and a scaling process, in addition to calibration of corner angles, and may process to remove measurement errors or mistakes of the indoor structure information and create and output a more accurate and realistic interior floor plan.

Accordingly, the portable terminal 100 receives calibration setting information based on a user input or a laser measurement value (step S201), calibrates the angle and the node position according to the polygon calibration process through the calibration unit 139 on the basis of the inputted calibration setting information (step S203), and processes calibration of wall according to the polygon scaling process (step S205).

Accordingly, the calibration unit 139 outputs an interior floor plan based on the calibrated indoor structure information (step S207), and the portable terminal 100 may store or upload the calibrated indoor structure information according to a confirmation input of the user corresponding to the outputted interior floor plan.

Here, the calibration setting information may include polygon calibration information or polygon scaling calibration setting information, and each calibration process may be selectively executed according to the setting information.

In addition, whether or not to execute the calibration process may be determined according to the form, shape or characteristic of a polygon acquired from the indoor structure information.

Accordingly, the calibration unit 139 according an embodiment of the present invention may perform a selective process of performing only a polygon calibration, performing only a polygon scaling calibration, or performing the polygon scaling calibration after performing the polygon calibration, according to the setting information and confirmation of whether or not the calibration can be performed according to setting of a threshold value for the calibration.

Hereinafter, the calibration process performed by the calibration unit 139 as described above will be described in more detail by dividing the calibration process into a polygon calibration process and a polygon scaling calibration process.

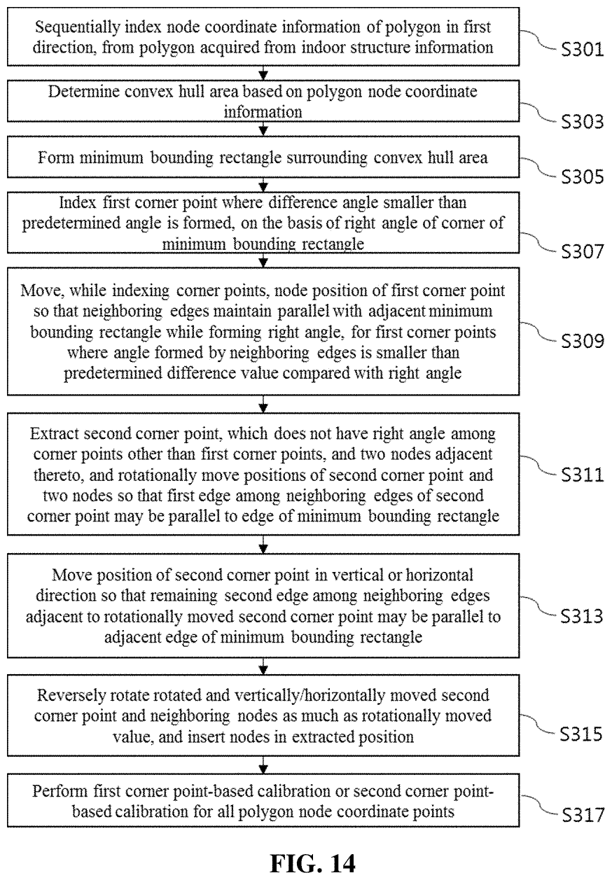

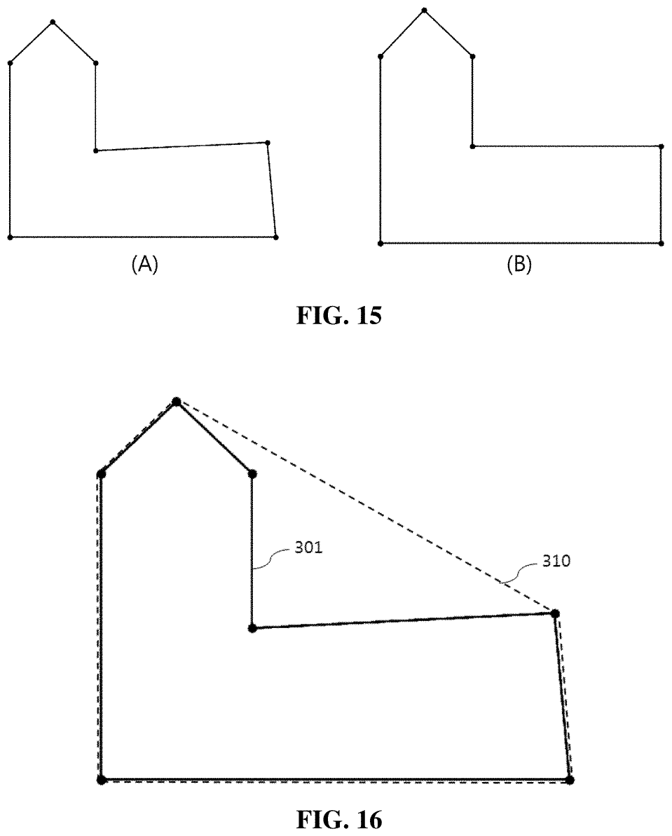

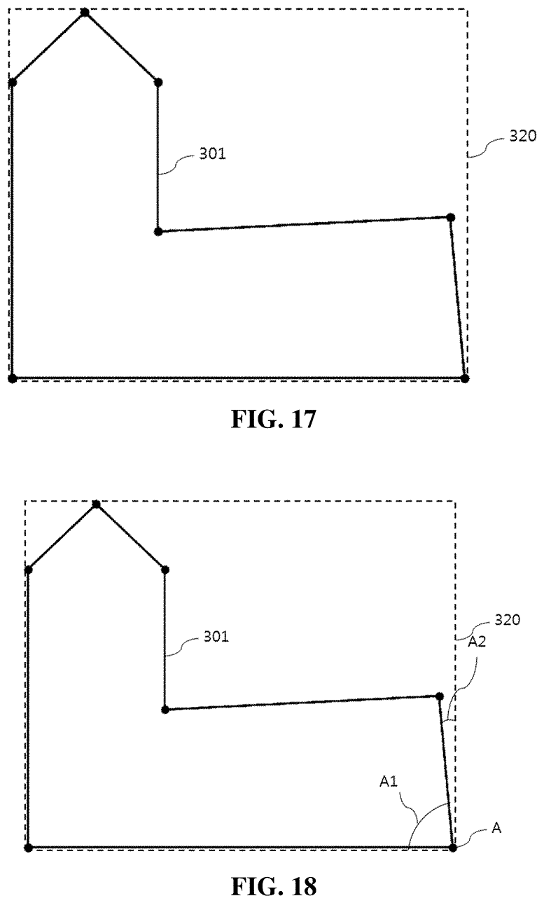

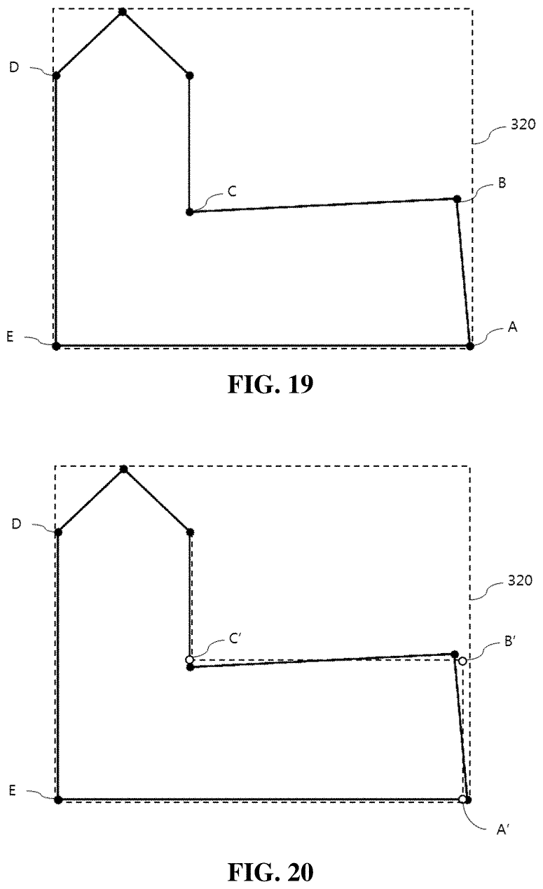

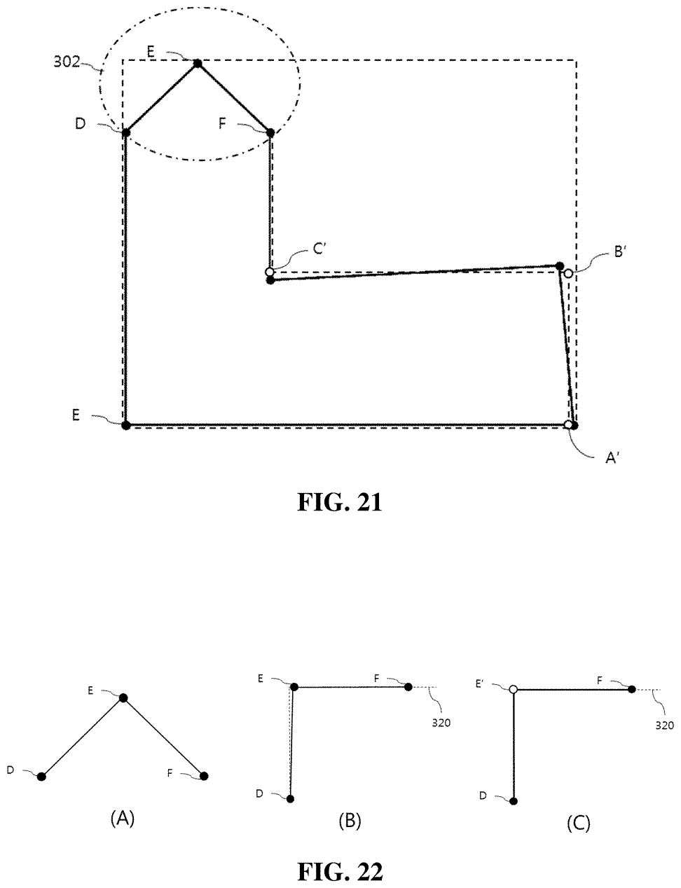

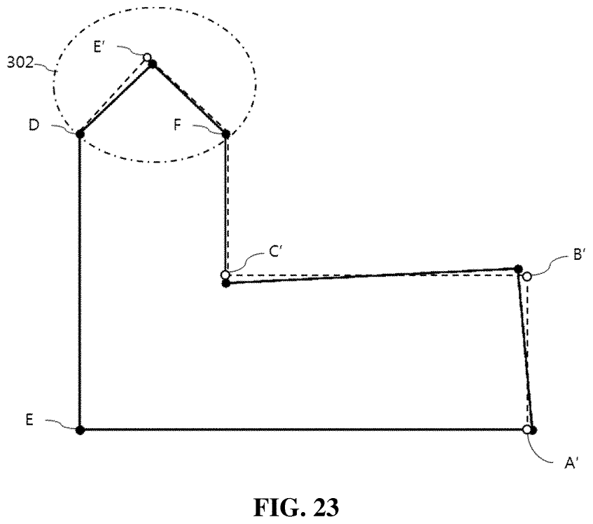

FIG. 14 is a flowchart illustrating an angle and node position calibration process based on polygon calibration according to an embodiment of the present invention, and FIGS. 15 to 23 are views showing an example of the calibration process in steps.

According to an embodiment of the present invention, since the coordinate point operation and corner location calculation process according to user input and measurement is a prediction process, it may be slightly different from the reality. Particularly, although corners are generally set to a right angle (90 or 270 degrees) in an indoor structure, partial deformation may be generated by an error in the measurement and prediction process.

For example, when a corner of a polygon is between 85 and 95 degrees or 265 and 275 degrees, it is actually a corner in a building, and calibration to 90 and 270 degrees respectively will more correspond with the actual interior floor plan information. However, since the shape and length of the overall indoor structure information may not be maintained when only a specific angle is simply modified, a more detailed calibration is required.

Accordingly, the calibration unit 139 may adjust the corner angle between walls to be a right angle (90 or 270 degrees) while maintaining the shape of the indoor structure information by performing calibration for calibrating the overall node position according to the polygon information acquired from the indoor structure information. This may be referred to as an angle and node position calibration process based on polygon calibration.

FIG. 15(A) is a view showing a polygon according to the indoor structure information before the polygon calibration, and FIG. 15(B) is a view showing a polygon calibrated according to the indoor structure information after the polygon calibration. As shown in FIG. 15, the polygon calibration allows construction of indoor structural information in a more realistic form close to actual measurement as the overall shape is maintained while calibrating some of node positions based on user input or prediction error to a right angle.

A calibration process for this purpose will be described in more detail. First, referring to FIG. 14, the calibration unit 139 acquires polygon information from indoor structure information for performing polygon calibration, and sequentially indexes node coordinate information of the polygon from the polygon in the first direction (step S301).

Then, the calibration unit 139 determines a convex hull area based on the indexed polygon node coordinates (step S303).

The convex hull area may mean a convex polygonal area configured to include all the remaining nodes when some of the points (nodes) configuring the polygon are connected. Various general algorithms may be used to determine the convex hull area, and an example thereof is a Graham's scan method that can be performed within O(n) time according to sorting of the nodes.

This is a method of configuring a list in which edges of the nodes are sorted clockwise or counterclockwise and determining whether a node configures the convex hull according to whether the node is included in the convex hull area while sequentially indexing the nodes clockwise or counterclockwise.

FIG. 16 is a view showing an example of a determined convex hull, and referring to FIG. 16, a convex hull 310 which can include all the nodes of the polygon 301 acquired from the indoor structure information may be determined.

Next, the calibration unit 139 forms a minimum bounding rectangle surrounding the convex hull area (step S305).

The minimum bounding rectangle may be a rectangle of a minimum size surrounding the convex hull area and may be a rectangle of a smallest size surrounding the polygon 301 as a result.

FIG. 17 is a view showing an example of a rectangle formed at a minimum size, and referring to FIG. 17, a minimum bounding rectangle 320 of a smallest size surrounding the polygon 301 acquired from indoor structure information may be formed.

Next, the calibration unit 139 indexes a first corner point where a difference angle smaller than a predetermined angle is formed, on the basis of the right angle of a corner of the minimum bounding rectangle (step S307).

More specifically, referring to FIG. 18, a first angle A1 and a second angle A2 may be formed at the corner point A with respect to the minimum bounding rectangle 320. In addition, A2 may be smaller than, for example, a difference angle of 10 degrees set in advance. In this case, the calibration unit 139 may index the corner point A as a first corner point. When indexing of the first corner point like this is completed for all nodes, a calibration process corresponding to the indexed first corner points may be processed.

Specifically, while indexing the corner points, the calibration unit 139 moves the node position of the first corner point to a position where the neighboring edges are maintained to be parallel with an adjacent minimum bounding rectangle 320 while forming a right angle, for the first corner points where an angle formed by neighboring edges is smaller than a predetermined difference value compared with the right angle (90 or 270 degrees) (step S309).

More specifically, referring to FIG. 19, A, B and C are examples of the first corner points where the angle formed by neighboring edges is smaller than a predetermined difference value compared with the right angle (90 or 270 degrees) of the minimum bounding rectangle.

Accordingly, as shown in FIG. 20, the position coordinates may be moved A to A′, B to B′ and C to C′, and edges formed by the position coordinates may be adjusted to maintain the parallel state with the edge of the adjacent minimum bounding rectangle 320.

As it is maintained to be parallel to the minimum bounding rectangle 320, the effect and the deformation between a previous corner angle and a next corner angle are minimized, and thus the overall polygonal shape can be maintained.

In addition, when the angles of the other first corner points are already calibrated to a right angle through movement of position of any one among the first corner points A, B, and C, the additional process of indexing and moving the positions of the other first corner points may be omitted.

Meanwhile, the calibration unit 139 extracts a second corner point, which does not have a right angle among the corner points other than the first corner points, and two nodes adjacent thereto, and rotationally moves the positions of the second corner point and the two nodes so that the first edge among the neighboring edges of the second corner point may be parallel to an edge of the minimum bounding rectangle (step S311).

Then, the calibration unit 139 moves the position of the second corner point in the vertical or horizontal direction so that the remaining second edge among the neighboring edges adjacent to the rotationally moved second corner point may be parallel to an adjacent edge of the minimum bounding rectangle (step S313), and reversely rotates the rotated and vertically/horizontally moved second corner point and the neighboring nodes as much as a rotationally moved value, and inserts the nodes in the extracted position (step S315).

As shown in FIG. 21, steps S311 to S315 are for indexing and calibrating a second corner point E which needs a right angle calibration among the corners not indexed as a first corner point directly compared with the minimum bounding rectangle 320, and a second corner point area 302 including the second corner point E and its neighboring two nodes D and F may be extracted and reinserted after a calibration is processed.

More specifically, as shown in FIG. 22(A), the extracted second corner point area 302 may include corner points D, E and F placed in the form of a triangle.

In addition, as shown in FIG. 22(B), the second corner point area 302 may be rotationally moved as a whole so that any one of the edges may be parallel to an edge of the minimum bounding rectangle 320 displayed as a dotted line. In FIG. 22(B), edge E-F may move to a position parallel to the minimum bounding rectangle 320. According to the movement like this, it is confirmed that the remaining edge E-D forms a predetermined error angle with the minimum bounding rectangle 320. In addition, the rotationally moved rotation angle may be stored in advance.

Accordingly, as shown in FIG. 22(C), the calibration unit 139 may calibrate the position of the second corner point E to a calibrated position E′ by moving the second corner point E in the vertical or horizontal direction so that the remaining second edge E-D among the neighboring edges adjacent to the rotationally moved second corner point may be parallel to an adjacent edge of the minimum bounding rectangle.

Next, the calibration unit 139 may reversely rotate the second corner point E′ and the neighboring nodes E and F, which are rotated and vertically/horizontally moved, as much as rotationally moved on the basis of the rotation angle stored in advance, and inserts them in the extracted position.

Here, the calibration unit 139 calibrates only the position of the second corner point positioned at the center among all the nodes of the second corner point area 302 in order to maintain the overall shape by positioning the remaining second edge E-D to be parallel to the minimum bounding rectangle 320, and it is since that if any one of the neighboring nodes, not the center point, is moved to calibrate the angle, the overall shape may be deformed again.

In addition, the calibration unit 139 may perform calibration for all coordinate points of the nodes of the polygon which need first corner point-based calibration or second corner point-based calibration, and output a result of the calibration (step S317). The overall shape after the calibration is completed according thereto is shown in FIG. 23. Referring to FIG. 23, since the overall shape is processed to be deformed in accordance with the right angle as the positions of existing corner points A, B, C and E are changed to A′, B′, C′ and E′, the calibration process may be completed.

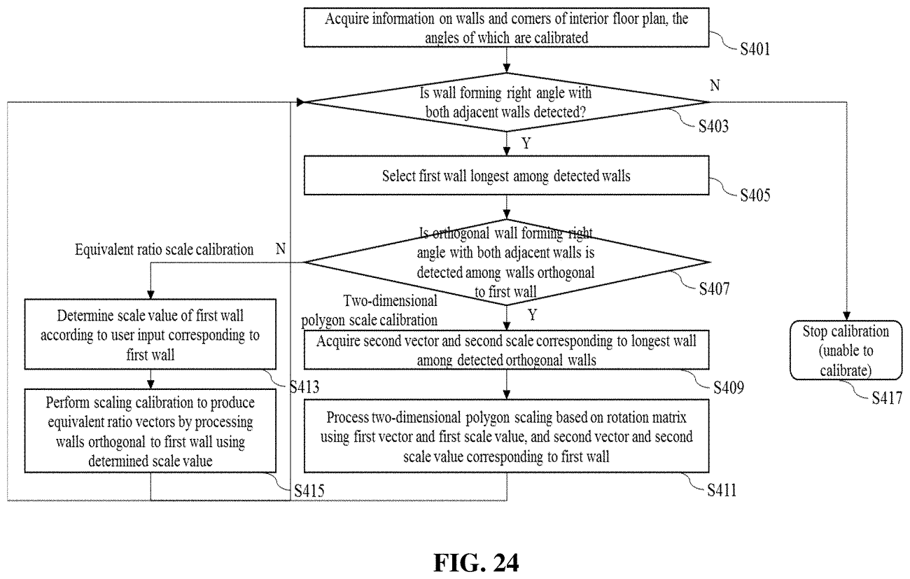

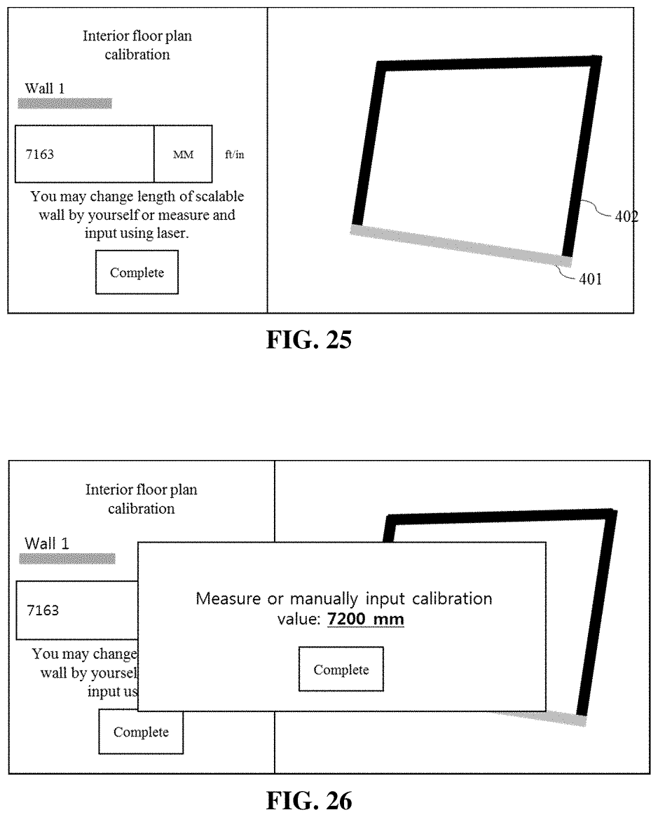

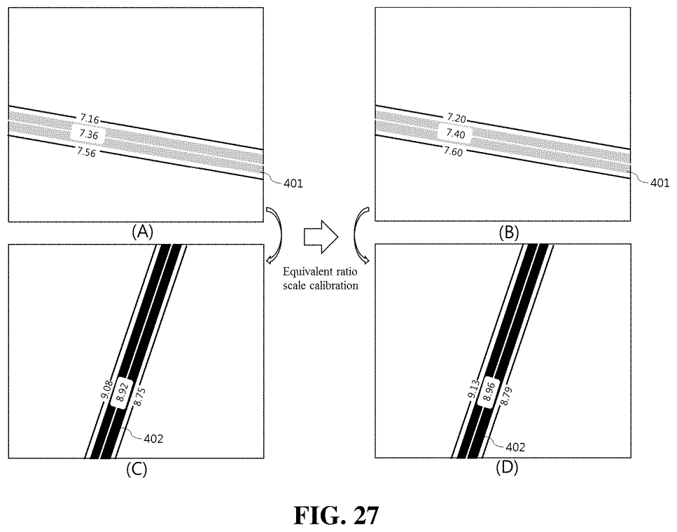

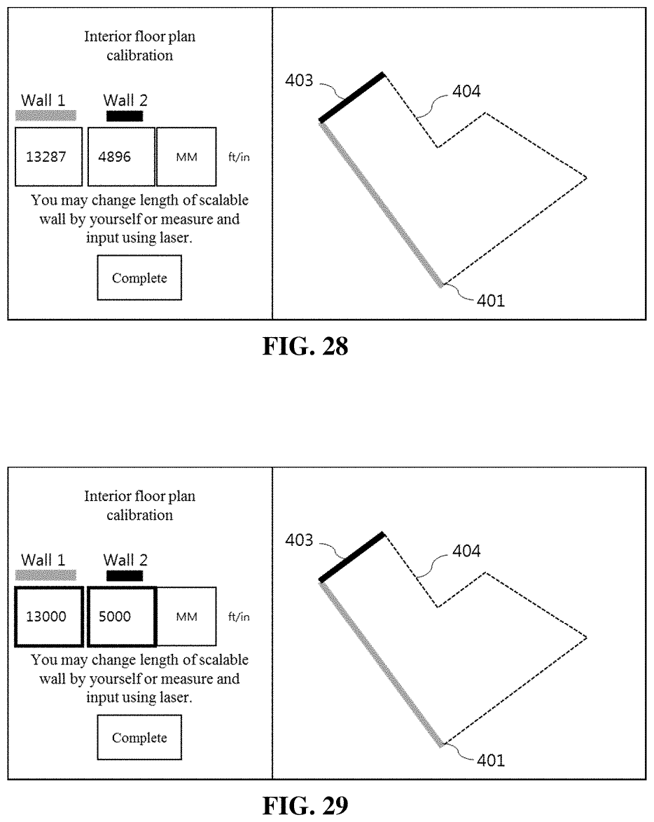

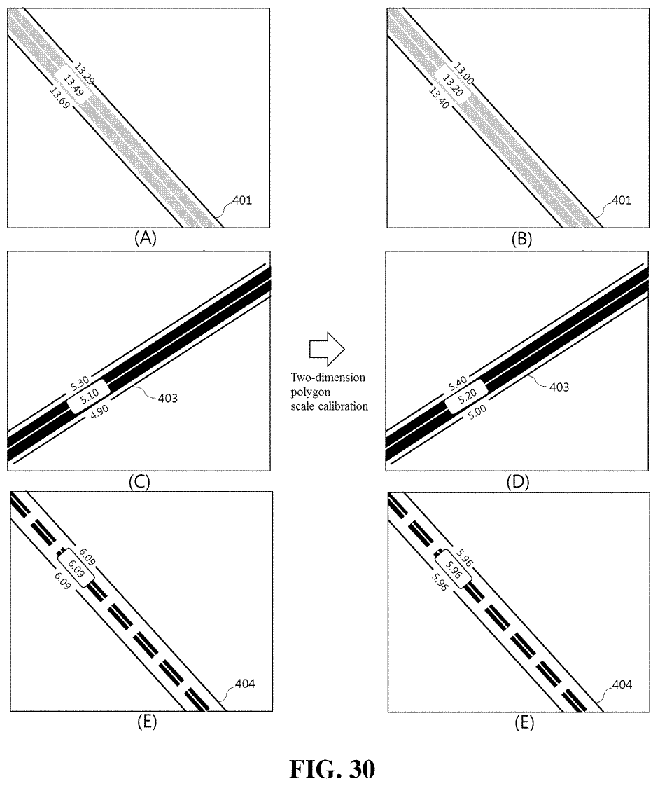

FIG. 24 is a flowchart illustrating a polygon scaling calibration process according to an embodiment of the present invention.

According to an embodiment of the present invention, accuracy of the length of a wall according to user input and measurement may vary according to the function and performance of the portable terminal 100. Accordingly, the calibration unit 139 according to an embodiment of the present invention may perform a proper scaling calibration corresponding to the length of a wall after the polygon calibration is completed.

However, when simply the wall length is calibrated, the overall polygonal shape of the indoor structure information is not maintained and a closed loop cannot be formed, and thus efficient calibration of the wall length is needed while minimizing user input into the interface.

Accordingly, the calibration unit 139 may adjust the walls to have a more accurate length value overall while maintaining the polygonal shape of the indoor structure information by detecting scalable reference walls according to polygon information acquired from the indoor structure information, receiving a calibration value corresponding thereto, and performing scaling on all the other remaining walls. This allows convenient calibration while minimizing user input, and this may be referred to as a polygon scaling calibration process.

To this end, referring to FIG. 24, first, the calibration unit 139 acquires information on walls and corners of an interior floor plan, the angles of which are calibrated (step S401).

Then, the calibration unit 139 confirms whether a wall forming a right angle with both adjacent walls is detected (step S403).

More specifically, for example, the calibration unit 139 may distinguish a wall forming a right angle with both adjacent walls by normalizing vectors of the walls (edges) acquired from the polygon information of the interior floor plan and confirming whether the absolute value of the inner product between two adjacent walls is a value within a predetermined range corresponding to 0.

Here, the wall forming a right angle with both adjacent walls may be a wall that can be calibrated by receiving a calibration value, and accordingly, the wall like this may be referred to as a scalable wall.

When scalable walls are detected, the calibration unit 139 selects a first wall (longest scalable wall) longest among the detected scalable walls (step S405).

Then, the calibration unit 139 confirms whether an orthogonal scalable wall forming a right angle with both adjacent walls is detected again among the walls orthogonal to the first wall (step S407).

Here, the calibration unit 139 drives an equivalent ratio scale calibration module when an orthogonal scalable wall like this is not detected and drives a two-dimensional polygon scale calibration module when the orthogonal scalable wall is detected, to execute a different scale calibration process.

First, when an orthogonal wall forming a right angle with both adjacent walls is not detected and an equivalent ratio scale calibration is driven, the calibration unit 139 determines a scale value of the first wall according to user input corresponding to the first wall (step S413).

Then, the calibration unit 139 performs scaling calibration of processing the walls orthogonal to the first wall using the determined scale value and producing them as equivalent ratio vectors (step S415).

For example, if it is assumed that a previously measured value of the first wall is A, the calibration unit 139 may acquire a calibration value B corresponding to the scalable first wall according to user input. Accordingly, the scale value may be calculated as B/A.

Then, the calibration unit 139 may process two-dimensional coordinate conversion to apply the value calculated as the scale value B/A to the vector of an orthogonal wall connected to the first wall, and perform scaling by applying the coordinate-converted scale value to the orthogonal wall connected to the first wall. For example, when a scale value corresponding to the first wall is applied to (2, 3), a scale vector that will be applied to the orthogonal wall is (−3, 2) and may be converted while maintaining an equivalent ratio.

Meanwhile, when an orthogonal scalable wall is detected, the calibration unit 139 acquires a second vector and a second scale value from the longest wall among the detected orthogonal scalable walls according to the two-dimensional polygon scale calibration process (step S409), and processes two-dimensional polygon scaling based on a rotation matrix using a first vector and the first scale value, and the second vector and the second scale value corresponding to the first wall (step S411).

Here, the calibration unit 139 may perform a scaling process which maintains the overall shape corresponding to each of the walls by processing two-dimensional polygon scaling based on a rotation matrix using existing corner location information of a calibration target, the first vector and the first scale value, and the second vector and second scale value corresponding to the first wall.

Describing the process based on a rotation matrix in more detail, the calibration unit 139 calculates a first relative angle (RelativeAngle) between the first vector and the X-axis (1, 0) and rotates all the nodes in a calibration target area in the X-axis direction according to the first relative angle using the rotation matrix.

Then, the calibration unit 139 performs a multiplication operation of multiplying

X coordinate values of the rotated nodes by the first scale value and performs reverse rotation (−RelativeAngle) on the nodes as much as the first relative angle.

The calibration unit 139 calculates a second relative angle (RelativeAngle) between the second vector and the X-axis (1, 0) and rotates all the nodes in a calibration target area in the X-axis direction according to the second relative angle using the rotation matrix.

Then, the calibration unit 139 performs a multiplication operation of multiplying X coordinate values of the rotated nodes by the second scale value and performs reverse rotation (-RelativeAngle) on the nodes as much as the second relative angle.

According to the process like this, it may be possible to adjust the walls to have a more accurate length value overall while maintaining the polygonal shape of the indoor structure information.

FIGS. 25 to 30 are views showing an example of a user interface for polygon scaling and a calibration result.

First, FIGS. 25 to 27 are views showing an input and a result according to equivalent ratio scaling, and referring to FIG. 25, the portable terminal 100 may output scalable walls detected by the calibration unit 139 described above on the display through the user interface and show that only corresponding walls may be calibrated according to user input.

As shown in FIG. 25, only Wall 1 is the first wall 401, of which the walls connected to both ends are orthogonal, and a message informing that overall scaling of the wall according to calibration input is possible may be displayed through the portable terminal 100.

In addition, as shown in FIG. 26, the user may measure a calibration value corresponding to the scalable wall using the measurement unit 120 or input the calibration value by himself or herself.

Accordingly, as shown in FIG. 27, a result of processing an equivalent ratio scale calibration by applying a scale ratio according to scale calibration corresponding to the first wall 401 to the remaining orthogonal walls 402 may be outputted through the portable terminal 100.

That is, if the length of the existing first wall 401 is calibrated from 7.163 m to 7.200 m as shown in FIGS. 27(A) and 27(B), the scale value may be defined as 7,200/7,163=1.0051654335, and as shown in FIGS. 27(C) and 27(D), the length of the remaining orthogonal wall 402 according to the equivalent ratio scaling may also be scaled to 8.96 m by multiplying 8.92 m and 1.0051654335.

Meanwhile, FIGS. 28 to 30 are views showing an input and a result according to two-dimensional polygon scaling, and referring to FIG. 28, the portable terminal 100 may output scalable walls detected by the calibration unit 139 described above on the display through the user interface and show that only corresponding walls may be calibrated according to user input.

As shown in FIG. 28, there may exist a first wall 401 of a length of 13,287 mm, of which the walls connected to both ends are orthogonal, and a second wall 403 of a length of 4,896 mm, of which the walls connected to both ends with respect to the first wall are orthogonal, and a message informing that overall scaling of the wall according to each calibration input is possible may be displayed through the portable terminal 100.

In addition, as shown in FIG. 29, the user may measure calibration values of 13,000 mm and 5,000 mm corresponding to the scalable walls using the measurement unit 120 or input the calibration values by himself or herself.

Accordingly, as shown in FIG. 30, a result of applying a scale calibration corresponding to the first wall 401, a scale calibration corresponding to the second wall 402 corresponding thereto, and a two-dimensional polygon scaling calibration based on a rotation matrix corresponding to the remaining orthogonal wall 404 may be outputted through the portable terminal 100.

That is, if the length of the first wall 401 is calibrated from 13,287 mm to 13,000 mm as shown in FIGS. 30(A) and 30(B), the first scale value may be defined as 0.9783999398, and if the length of the second wall 403 is calibrated from 4,896 mm to 5,000 mm as shown in FIGS. 30(C) and 30(D), the second scale value may be defined as 1.0212418301. In addition, the length of the remaining orthogonal wall 404 according to the two-dimension polygon scaling calibration may be scaled from 6.09 m to 5.96 m that is multiplied by the first scale value as shown in FIGS. 30(E) and 30(F).

Accordingly, convenient calibration is allowed while minimizing user input, and the overall ratio and the two-dimensional polygon shape can be maintained.

The method according to the present invention described above may be manufactured as a program to be executed in a computer and stored in a computer-readable recording medium, and examples of the computer-readable recording medium are ROM, RAM, CD-ROM, a magnetic tape, a floppy disk, an optical data storage device and the like, and those implemented in the form of carrier wave (e.g., transmission through the Internet) are also included.

The computer-readable recording medium may be distributed in computer systems connected through a network, and computer-readable codes may be stored and executed in a distributed manner. In addition, function programs, codes and code segments for implementing the method may be easily inferred by the programmers in the field of the present invention.

In addition, although preferred embodiments of the present invention are shown and described above, the present invention is not limited to the specific embodiments described above, and various modified embodiments can be made by those skilled in the art without departing from the gist of the present invention claimed in the claims described below, and these modified embodiments should not be individually understood from the spirit and prospect of the present invention.

1. A portable terminal operation method comprising the steps of:
acquiring measurement information corresponding to a first coordinate point of a first wall and a second coordinate point of the first wall;
determining structure information of the first wall connecting the first coordinate point and the second coordinate point on the basis of a linear function operation of the first coordinate point and the second coordinate point; and
completing indoor structure information including one or more closed spaces, according to sequential connection processing of other walls in a first direction corresponding to the first wall.

2. The method according to claim 1, wherein the step of determining structure information includes the steps of:
acquiring user input and measurement information corresponding to the first coordinate point of the first wall;
calculating location information of a two-dimensionally converted first coordinate point on the basis of user's location information, three-dimensional angle information and distance information acquired from the measurement information;
acquiring user input and measurement information corresponding to the second coordinate point of the first wall;
calculating location information of a two-dimensionally converted second coordinate point on the basis of three-dimensional angle information and distance information acquired from the measurement information;
determining structure information of the first wall connecting the first coordinate point and the second coordinate point on the basis of a linear function operation; and
creating the indoor structure information including the structure information of the first wall.

3. The method according to claim 2, wherein the step of calculating location information includes the step of calculating information on a first parallel distance to the first wall, which is calculated on the basis of information on a first pointing distance from a current position to the first wall of a pointed direction and the three-dimensional angle information, as distance information corresponding to the first coordinate point of the first wall.

4. The method according to claim 3, wherein the three-dimensional angle information includes pitch information, and information on the parallel distance to the first wall, which corresponds to the first coordinate point, is calculated by a multiplication operation of multiplying the pointing distance information by cosine-operated pitch information.

5. The method according to claim 4, wherein the three-dimensional angle information includes yaw information, and the first coordinate information is calculated by operation of mathematical expression 1 when parallel distance information of first coordinate (x, y) is 1, pitch information is θ, yaw information is ϕ, and current user's location information is x0 and y0, wherein
(x, y)=(l*cos(θ)*(−sin(ϕ))+x0, l*cos(θ)*(−cos(ϕ))+y0). (Mathematical expression 1)

6. The method according to claim 2, wherein the step of completing indoor structure information further includes the steps of:
determining structure information of the second wall adjacent to the first wall in the first direction; and
processing connection of the first wall and the second wall according to a corner information operation of the structure information of the first wall and the second wall on the basis of linear function information of the first wall and linear function information of the second wall.

7. The method according to claim 1, further comprising the step of performing a calibration process of the indoor structure information according to user input.

8. The method according to claim 7, wherein the calibration process includes an angle and node position calibration according to a polygon calibration process corresponding to the indoor structure information.

9. The method according to claim 8, wherein the polygon calibration process includes a process of calibrating a corner angle to a right angle through movement of a position of a corner point based on polygon node coordinate information corresponding to the indoor structure information.

10. The method according to claim 9, wherein the process of calibrating a corner angle to a right angle includes a process of determining a convex hull area based on the polygon node coordinate information corresponding to the indoor structure information, forming a minimum bounding rectangle using the convex hull area, and performing movement of a position of a corner point.

11. The method according to claim 7, wherein the calibration process includes a scaling calibration process of a wall corresponding to the indoor structure information, wherein the scaling calibration process includes a process of detecting a wall orthogonal to both adjacent walls from the indoor structure information as a scalable wall, and performing any one among an equivalent ratio scale calibration and a two-dimensional polygon scale calibration according to input of a calibration value corresponding thereto.

12. The method according to claim 11, wherein the equivalent ratio scale calibration is performed when an orthogonal wall that forms a right angle with both adjacent walls among walls orthogonal to the first wall, and includes a process of performing, when a scale value of the first wall is determined according to input of the calibration value corresponding to the first wall, scaling calibration of processing the walls orthogonal to the first wall using the determined scale value to produce equivalent ratio vectors.

13. The method according to claim 11, wherein the two-dimensional polygon scale calibration is performed when an orthogonal wall that forms a right angle with the both adjacent walls among walls orthogonal to the first wall, and includes a process of acquiring a first vector and a first scale value of the first wall, and a second vector and a second scale value of the second wall according to input of a calibration value corresponding to the first wall and a second wall longest among the detected orthogonal walls, and two-dimensionally scaling on the basis of a rotation matrix.

14. The method according to claim 1, further comprising the step of storing the completed indoor structure information as interior floor plan information of a building.

15. A portable terminal comprising:
a measurement unit acquiring measurement information corresponding to a first coordinate point of a first wall and a second coordinate point of the first wall; and
a space information creation unit determining structure information of the first wall connecting the first coordinate point and the second coordinate point on the basis of a linear function operation of the first coordinate point and the second coordinate point, and completing indoor structure information including one or more closed spaces, according to sequential connection processing of other walls in a first direction corresponding to the first wall.

16. The terminal according to claim 15, wherein the measurement unit acquires user input and measurement information corresponding to the first coordinate point of the first wall, and acquires user input and measurement information corresponding to the second coordinate point of the first wall, wherein the space information creation unit further includes a coordinate processing unit for calculating location information of a two-dimensionally converted first coordinate point on the basis of user's location information, three-dimensional angle information and distance information acquired from the measurement information, and calculating location information of a two-dimensionally converted second coordinate point on the basis of three-dimensional angle information and distance information acquired from the measurement information, and the space information creation unit determines structure information of the first wall connecting the first coordinate point and the second coordinate point on the basis of a linear function operation, and creates the indoor structure information including the structure information of the first wall.

17. The terminal according to claim 16, wherein the coordinate processing unit calculates information on a first parallel distance to the first wall, which is calculated on the basis of information on a first pointing distance from a current position to the first wall of a pointed direction and the three-dimensional angle information, as distance information corresponding to the first coordinate point of the first wall.

18. The terminal according to claim 15, further comprising a calibration unit performing a calibration process of the indoor structure information according to user input.

19. The terminal according to claim 18, wherein the calibration process includes an angle and node position calibration according to a polygon calibration process corresponding to the indoor structure information, and the polygon calibration process includes a process of calibrating a corner angle to a right angle through movement of a position of a corner point based on polygon node coordinate information corresponding to the indoor structure information.

20. The terminal according to claim 18, wherein the calibration process includes a scaling calibration process of a wall corresponding to the indoor structure information, wherein the scaling calibration process includes a process of detecting a wall orthogonal to both adjacent walls from the indoor structure information as a scalable wall, and performing any one among an equivalent ratio scale calibration and a two-dimensional polygon scale calibration according to input of a calibration value corresponding thereto.
